(19) United States
(12) Patent Application Publication
(10) Pub. No.: US 2022/0311373 A1
(43) Pub. Date: Sep. 29, 2022

(54) PHOTOVOLTAIC DEVICE AND SYSTEM

(71) Applicant: PALZIV EIN HANAZIV AGRICULTURAL COOPERATIVE SOCIETY LTD., Ein Hanatziv (IL)

(72) Inventors: Lior HILLEL, Ein Hanatziv (IL); Yosef BENSHALOM, Ein Hanatziv (IL)

(73) Assignee: PALZIV EIN HANAZIV AGRICULTURAL COOPERATIVE SOCIETY LTD., Ein Hanatziv (IL)

(21) Appl. No.: 17/628,050

(22) PCT Filed: Jun. 24, 2020
(86) PCT No.: PCT/IL2020/050702

§ 371 Date: Jan. 18, 2022

Related U.S. Application Data
(60) Provisional application No. 62/875,818, filed on Jul. 18, 2019.
(60) Provisional application No. 62/911,345, filed on Oct. 6, 2019.
(60) Provisional application No. 62/980,384, filed on Feb. 23, 2020.

(51) Int. Cl. H02S 20/00; H02S 30/10; H02S 30/20; H02S 20/30; B32B 5/18; B32B 1/00; B32B 27/30; B32B 27/36; B32B 27/34; B32B 27/32; B32B 27/06; B32B 3/08; B32B 3/30; B32B 5/02; B32B 27/20

(52) U.S. Cl. CPC H02S 20/00; H02S 30/10; H02S 30/20; H02S 20/30; B32B 5/18; B32B 1/00; B32B 27/308; B32B 27/36; B32B 27/34; B32B 27/32; B32B 27/065; B32B 3/08; B32B 3/30; B32B 5/024; B32B 5/022; B32B 27/20; H02S 20/23

(57) ABSTRACT

A photovoltaic panel support and system comprising a cross-linked closed cell foam structure and one or more photovoltaic panels is coupled to the cross-linked closed cell foam structure, is disclosed.

### TECHNICAL FIELD

The present disclosure pertains generally to a lightweight foam-based support and systems with a mounted photovoltaic element for portable and mobile solar energy generating.

### BACKGROUND

There is great interest in sustainable energy as a substitute to fossil-fuel based energy. Many countries have stipulated that they will gradually move out of fossil fuels in the near future, and several international treaties likewise address the matter. Improvements in photovoltaic elements and lightweight, portable systems containing photovoltaic elements capable of generating electricity from the sun are needed in order to induce broader utilization of solar energy by government, business organizations, and households.

### SUMMARY

A photovoltaic panel support is provided, the support comprising a cross-linked closed cell foam structure having a first surface defined by a length and a width, and an opposing second surface separated from the first surface by a thickness, and a rigid photovoltaic panel or a flexible photovoltaic panel coupled to the first surface of the cross-linked closed cell foam structure, the rigid or the flexible photovoltaic panel comprising one or more photovoltaic elements.

In one example, the cross-linked closed cell foam structure further comprises a semi-rigid or rigid film directly coupled on one or both of the first surface and the opposing second surface. In another example, alone or in combination with the previous example, the rigid photovoltaic panel or the flexible photovoltaic panel is directly coupled to the semi-rigid or rigid film.

In another example, alone or in combination with any one of the previous examples, the cross-linked closed cell foam structure comprises low density polyethylene, low density polyethylene copolymers, metallocene ethylene copolymers, ethylene vinyl acetate copolymers and blends thereof.

In another example, alone or in combination with any one of the previous examples, the semi-rigid or rigid film is high density polyethylene or ultrahigh molecular weight polyethylene.

In another example, alone or in combination with any one of the previous examples, the cross-linked closed cell foam structure comprises one or more cutouts at least partially through the thickness.

In another example, alone or in combination with any one of the previous examples, the flexible photovoltaic panel comprises acrylic, polyester, polyamide, polypropylene, or a composite material reinforced with fibers of glass, carbon, or nylon.

In another example, alone or in combination with any one of the previous examples, where one or more of the cross-linked closed cell foam structures supports are arranged in an array. In another example, alone or in combination with any one of the previous examples, one or more of the photovoltaic panels are arranged horizontally or at an inclination relative to a horizon of about 2 degrees to about 80 degrees. In another example, alone or in combination with any one of the previous examples, at least a portion of the cross-linked closed cell foam structure is concave.

A photovoltaic support system is provided, the system comprising a cross-linked closed cell flexible foam structure having a first surface defined by a length and a width, and an opposing second surface separated from the first surface by a thickness, a rigid photovoltaic panel or a flexible photovoltaic panel comprising one or more photovoltaic elements. In one example, the support system further comprises a semi-rigid or rigid film directly coupled to the first surface or to both the first surface and the second surface, wherein the semi-rigid or rigid film coupled to the first surface is configured to receive the rigid or the flexible photovoltaic panel.

In another example, alone or in combination with any one of the previous examples, the support system further comprises a recess in the first surface and/or the semi-rigid or rigid film, the recess sized to receive the rigid or the flexible photovoltaic panel.

In another example, alone or in combination with any one of the previous examples, the cross-linked closed cell foam structure is arranged as a frame, the frame comprising: at least two longitudinal members; at least two cross-members configured for securing to the at least two longitudinal members; wherein the frame is configured to receive and secure the rigid or the flexible photovoltaic panel. In another example, alone or in combination with any one of the previous examples, at least a portion of the frame is concave.

In another example, alone or in combination with any one of the previous examples, the cross-linked closed cell flexible foam structure comprises: an outer frame comprising at least two longitudinal members and at least two cross-members; and an inner frame positioned within the outer frame, the inner frame pivotably coupled to the outer frame, wherein the inner frame is configured for receiving and securing the rigid or the flexible photovoltaic panel without adhesive or fastenings such that the rigid or the flexible photovoltaic panel is adjustably inclinable about 2 degrees to about 80 degrees relative to a horizon.

In another example, a method of reducing or eliminating evaporation of liquid is provided, the method comprising positioning, on at least a portion of a surface of a liquid body, a cross-linked closed cell foam structure having a first surface defined by a length and a width, and an opposing second surface separated from the first surface by a thickness, and a rigid photovoltaic panel or a flexible photovoltaic panel comprising one or more photovoltaic elements, the rigid or the flexible photovoltaic panel coupled to the first surface of a cross-linked closed cell foam structure, and reducing or eliminating evaporation of liquid from the surface of the liquid body.

In one example, the cross-linked closed cell foam structure further comprises a semi-rigid or rigid film directly coupled on one or both of the first surface and opposing second surface. In another example, alone or in combination with the previous example, the rigid or the flexible photovoltaic panel is directly coupled to the semi-rigid or rigid film.

In another example, alone or in combination with any one of the previous examples, the cross-linked closed cell foam structure comprises low density polyethylene, low density polyethylene copolymers, metallocene ethylene copolymers, ethylene vinyl acetate copolymers and blends thereof.

In another example, alone or in combination with any one of the previous examples, the semi-rigid or rigid film is high density polyethylene or ultrahigh molecular weight polyethylene. In another example, alone or in combination with any one of the previous examples, the flexible photovoltaic panel comprises acrylic, polyester, polyamide, polypropylene, or a composite material reinforced with fibers of glass, carbon, or nylon.

In another example, alone or in combination with any one of the previous examples, the cross-linked closed cell foam structure with the photovoltaic panels is arranged in an array, where at least one of the photovoltaic panel is arranged horizontally or at an inclination relative to a horizon of about 2 degrees to about 80 degrees. In another example, alone or in combination with any one of the previous examples, the cross-linked closed cell flexible foam structure is a frame comprising at least two longitudinal members; at least two cross-members configured for securing to the at least two longitudinal members; wherein the frame receives and secures the rigid or the flexible photovoltaic panel without adhesive or fastenings. In another example, alone or in combination with any one of the previous examples, the photovoltaic panel is concavely arranged on a frame. In another example, alone or in combination with any one of the previous examples, the frame is pivotable such that at least one of the photovoltaic panel is arranged horizontally or adjustably inclinable to an inclination of about 2 degrees to about 80 degrees relative to a horizon.

### BRIEF DESCRIPTION OF THE DRAWINGS

Other objects and advantages of the present disclosure will be apparent from the specification and claims, when considered in connection with the attached drawings, where like characters represent like parts and in which:

FIGS. 1A and 1B depicts related art photovoltaic support systems;

FIGS. 2A, 2B, and 2C depict examples of closed cell foam support structures disclosed and described herein;

FIG. 3 depicts an example of a flexible photovoltaic panel (PV);

FIGS. 4A and 4B depict various perspective views of a photovoltaic panel support as disclosed and described herein;

FIG. 5A depicts a sectional view along sectional line 4-4 of the photovoltaic panel support of FIG. 4B, as disclosed and described herein;

FIG. 5B depicts a sectional view of an alternative photovoltaic panel support, as disclosed and described herein;

FIG. 6A depicts another exemplary photovoltaic panel support as disclosed and described herein;

FIG. 6B depicts another exemplary photovoltaic panel support as disclosed and described herein;

FIG. 7A depicts another exemplary photovoltaic panel support as disclosed and described herein;

FIG. 7B depicts another exemplary photovoltaic panel support as disclosed and described herein;

FIG. 8 depicts a top plan view of an exemplary photovoltaic support system as disclosed and described herein;

FIG. 9 depicts an exemplary photovoltaic support system as disclosed and described herein positioned on a liquid surface;

FIG. 10 depicts an exemplary photovoltaic support system as disclosed and described herein;

FIGS. 11A, 11B, and 11C depict a top plan view, bottom perspective view and side plan view of an exemplary photovoltaic support as disclosed and described herein;

FIG. 12A depicts a top perspective view of an exemplary photovoltaic support system as disclosed and described herein;

FIG. 12B depicts a bottom perspective view of the photovoltaic support system of FIG. 12A;

FIGS. 13A and 13B depict an exploded un-assembled view and assembled view, respectively, of an exemplary photovoltaic support as disclosed and described herein;

FIGS. 13C and 13D depict an un-assembled view and assembled view, respectively, of the exemplary photovoltaic support system of FIG. 13B with photovoltaic member as disclosed and described herein;

FIG. 13E depicts a coupled plurality of the exemplary photovoltaic support systems of FIG. 13D as disclosed and described herein;

FIG. 13F is an enlarged view of exemplary coupling means as disclosed and described herein;

FIG. 14 depicts a top perspective view of an exemplary linear photovoltaic support system array as disclosed and described herein;

FIG. 15 depicts a top perspective view of an exemplary two-dimensional photovoltaic support system array as disclosed and described herein;

FIG. 16A depicts a top perspective view of an exemplary photovoltaic support as disclosed and described herein;

FIG. 16B depicts a section view along line 16B-16B of the photovoltaic support of FIG. 16A;

FIG. 17A depicts a top perspective view of an exemplary photovoltaic support system as disclosed and described herein;

FIG. 17B depicts a bottom perspective view of the photovoltaic support system of FIG. 17A;

FIGS. 18A and 18B, 18C and 18D depict a perspective view and a side view, respectively, of an exemplary photovoltaic support as disclosed and described herein; and

FIGS. 18C and 18D depict a perspective view and a bottom perspective view, respectively, of the exemplary photovoltaic support system of FIG. 18A with photovoltaic member as disclosed and described herein.

### DETAILED DESCRIPTION

As used herein, the term “machine direction,” or “MD,” refers to the direction of a running, continuous structure or film during the manufacture thereof, or the longitudinal dimension of an article when such dimension is greater than all other dimensions, with the exception of a square shaped article. As used herein, the term “cross direction,” or “CD,” refers to the direction that is essentially perpendicular to the machine direction. As used herein, a “surface” is defined by a length along the MD and a width along the CD. For a square shaped article, MD and CD can be used interchangeably.

As used herein, the terms “including,” “comprising,” or “having” and variations thereof encompass the items listed thereafter and equivalents thereof, as well as additional items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of this specification and the relevant art and will not be interpreted in an idealized or overly formal sense unless expressly defined herein.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

It will be understood that when an element is referred to as being “coupled” to another element, other elements or intervening elements may be present.

It will be understood that when an element is referred to as being “directly coupled” to another element, other elements or intervening elements are not present.

The term “monolithic” means an object that is a single, unitary piece formed or composed of a material without joints or seams.

The term “semi-rigid” as used herein refers to a construction that is not intended to substantially flex or substantially bend as part of its normal operation but has the capability of flexing and/or bending outside of its normal operation, i.e., not inflexible.

The term “rigid” as used herein refers to a construction that is not flexible or pliant, and is otherwise resisting change in form and substantially devoid of flexibility. Rigid is inclusive of a configuration that is substantially unable to bend or be forced out of shape without breaking or undergoing permanent deformation.

Existing solar farms utilize conventional glass-based (and often framed), rigid and heavy PV elements (as used on rooftops and land-based PV farms) and/or systems. These elements/systems require cumbersome metallic structures and are ordinarily of a mass unsuitable for relocation and/or transport. Conventional floating solar farms are floated on water using a rigid metallic floating structure having hollow buoys (at times filled with expansive polyurethane foam) for providing buoyancy of the photovoltaic elements. Transportation and handling of both the PV panels and the floating structure are difficult, time-consuming and require skilled workers. The assembly process is also time-consuming and costly. Typically, uses of such conventional floating solar farms are limited to large governmental or commercial projects, because of the substantial “set-up” cost, and non-portability. Such, drawbacks of the conventional floating solar farms rule out the exploitation of cost-effective use on small (or private) bodies of water or by small business or individuals. Moreover, the buoys of conventional floating solar farms themselves are vulnerable to piercing which will allow water penetration, necessitating intervention, and costly and time-consuming repair. Likewise, transport of such a rigid metallic structure with buoys is inefficient (basically, tantamount to transporting air). In addition, because the conventional structure is not flexible, possible damage and breakage may result in hostile weather and/or during transport.

The present disclosure provides a solution to the aforementioned technical problems of providing solar energy conversion that is simple and flexible to plan, master and execute. On the execution side, the solution is essentially “lay, plug and play.” For example, the present disclosure describes a closed cell foam support structure having generally (though not exclusively) a rectangular sheet shape form having disposed on one side thereof one or more flexible photovoltaic elements. One or more support structures can be assembled individually or collectively (as an array) in or on a defined area, such as a field, body of liquid, as a facade of a building, as roofing, or suspended vertically or at an angle above a vertical surface or from a horizontal surface, for example, as further discussed below.

Positioning and using the presently disclosed devices and system and/or coupling them together can be done by non-skilled users. Accessing the generated electrical power or diverting the same or portion thereof to a local facility or (“the grid”) can also be performed for example, by a professional electrician, in a manner similar to activating a conventional PV installation on one's roof. Thereafter, the present system immediately becomes operational and starts generating electricity and possibly revenue if sent to the grid.

More specifically, the present disclosure addresses an ease of transport, assembly (and dis-assembly), as well as an ease of maintenance of the presently disclosed devices and (and their storage, when needed), with the intention to render such presently disclosed devices and systems more accessible.

The presently disclosed devices and system provide a totally different approach, for example, to floating photovoltaic systems, making use of an innovative “carrier” material which is itself a buoy, in conjunction with light-weight photovoltaic modules. The presently disclosed device configuration is equally useful for land-based installation, either on the ground, or elevated above the ground, or on structures (i.e. façades and roofs), rendering it versatile and appealing to different users and working environments.

The presently disclosed devices and system can be used to exploit unused “real estate” e.g., available and non-exploited bodies of water for the purpose of generating electrical power. Moreover, a potential benefit of the presently disclosed devices and system when used on fresh water bodies is the reduction of evaporation, which is advantageous, for example, in arid regions.

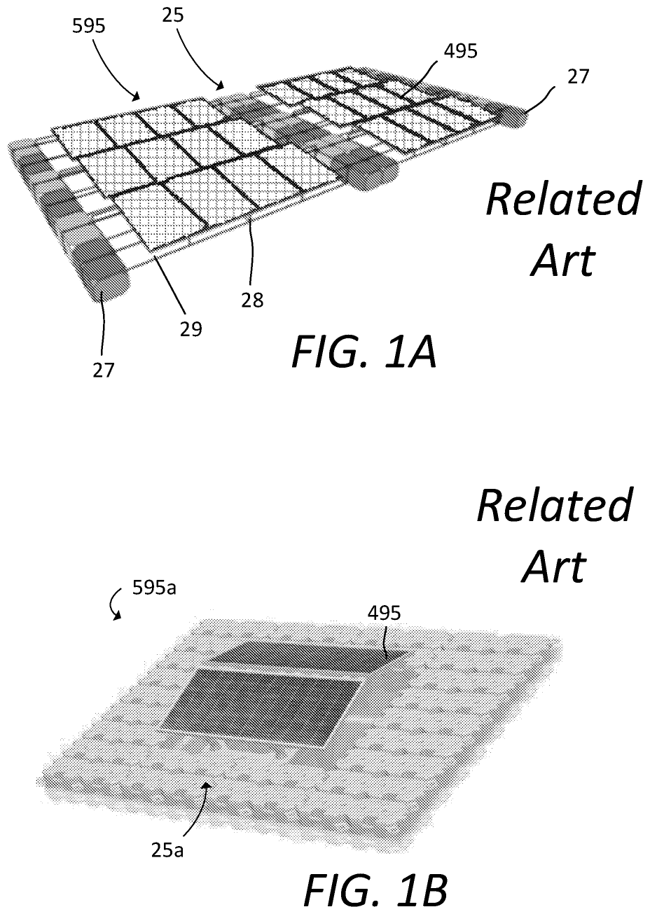

FIGS. 1A and 1B depict related art photovoltaic support systems having at least one of non-foamed photovoltaic support system 595, 595a having conventional glass-based solar panels 495. Support structure 25 of system 595 comprises flotation members 27, e.g., foamed/expanded polystyrene or polyurethane, connected in a frame-type fashion so as to provide a mounting platform for receiving conventional photovoltaic solar panels 495 secured to system 595. Flotation members 27 are connected by longitudinal members 29 and cross-members 28, which are fixedly coupled with cross members 926. Members 26, 28 and 29 can be plastic, including reinforced plastics, metal or wood. Likewise, system 595a has interlocking floatation members 25a forming a frame for conventional glass-based solar panels 495. The frame-type structure of this related art results in a system that is neither portable nor lightweight, necessitating unnecessary assembly/disassembly and transportation and limited flexibility in locating and positioning the system. Likewise, support systems based on fabric/membrane as carriers of for the PV modules and auxiliary elements, such as CF and RF series of products offered by Ocean Sun AS (Lysaker, Norway) have similar transportation and deployment issues and fail to remedy the technical problem of portability and deployment on surfaces other than liquid bodies.

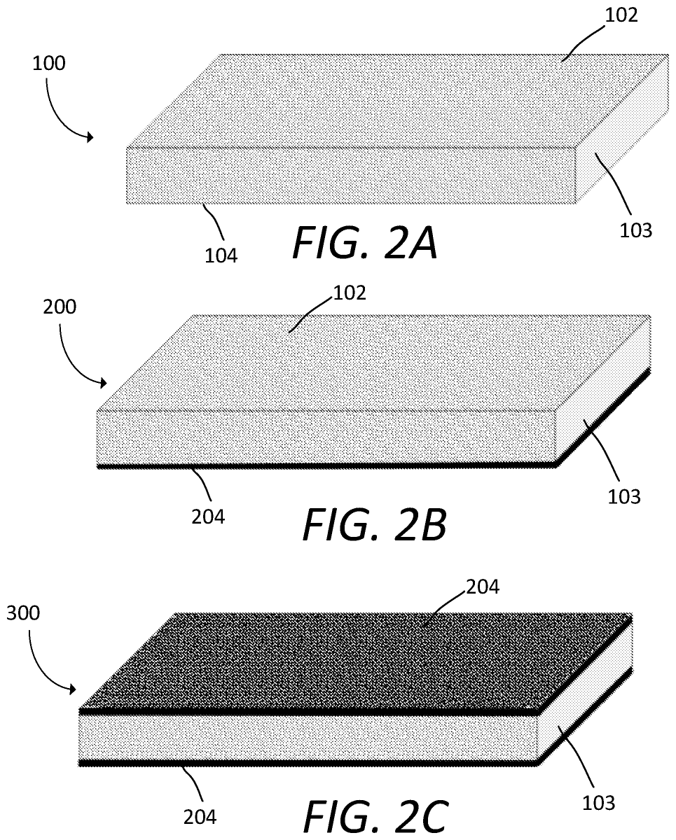

With reference to FIGS. 2A, 2B, and 2C, examples of presently disclosed closed cell foam support structures are depicted. With reference to FIG. 2A, support 100 is depicted as a closed cell foam 103 having a first surface 102 defined by a length and a width of the support and its corresponding opposed surface 104 providing a generally rectangular shape with both the dimensions of the longitudinal (or machine) direction and the width being greater than a thickness dimension defined by the distance separating surface 102 and surface 104 direction. In one example, the length to width ratio (L:W) is configured to adequately support a flexible photovoltaic element. In another example, the length to width ratio of the foam support 100 is 1:1 to 10:1. In one example, the distance separating surfaces 102 and 104 is about 10 mm to about 100 mm. Support 100 is depicted as rectangular, but can be of another geometrical shape, such as, substantially, circular, triangular, square, or substantially of pentagon, hexagon, octagon, or trapezoid shape. Support 100 can be shaped substantially as a parallelogram. Support 100 can be configured to interlock or otherwise connect or align with another supports of similar or dissimilar shape.

In one example, closed cell foam support 100 is composed of a sheet of cross-linked foam. The cross-linked foam can be of polyethylene (XLPE). In one example, low density polyethylene, low density polyethylene copolymers, metallocene ethylene copolymers, ethylene vinyl acetate copolymers, and blends thereof can be used. In one example, the cross-linked foam having about 20-22 mm thickness is in the range of about 2 kg/m² to about 4 kg/m² or about 2.4 kg/m² to about 4.8 kg/m² depending on the chosen density of the polymer and additives used to provide the foam. Such foam is commercially available from Palziv, Inc. (Ein Hanatziv, Israel).

In one example, the closed cell foam support 100 is cross-linked. The use of cross-linked polyethylene (PE) as the foam provides environmental degradation resistance, as well as long and stable service-life. Cross-linked PE foam is highly resistant to corrosion by water (both fresh and saltwater) and is resistant to growth of algae, and attachment of snails, mussels and the like.

The presently disclosed cross-linked foam structure is closed-cell and is resistant to absorption of water over long periods of time. The presently disclosed cross-linked foam structure is effective as a floating element, as it is often used for buoys. The presently disclosed cross-linked foam structure likewise acts as a thermal, acoustic, liquid and electrical insulator. The electrical insulation functionality of the cross-linked foam is advantageous to installation of the presently disclosed devices and system. The thermal and acoustic features are advantageous when installing the presently disclosed devices and system on roofs or facades of buildings, for example.

The foam or its precursor components can contain one or more additives that improve one or more physical or chemical properties of the foam or processability of the foam. The one or more additives can include fire-retardants, antimicrobials, conductivity enhancers (generating antistatic, dissipative, or conductive qualities of the foam), pigments (for color), anti-UV additives, additives for bio-degradability and other additives or combinations thereof.

As shown in FIG. 2B, support 200 has coupled thereto a semi-rigid or rigid film 204 on one surface, for example, corresponding to the foam's longitudinal direction, support 200 being depicted as having a general rectangular shape as described for support 100. In one example, support 200 has semi-rigid or rigid film 204 directly coupled thereto. In one example, support 200 has semi-rigid or rigid film 204 laminated to surface 102 and/or 104. The side edges of support 200 can be contacted with the semi-rigid or rigid film 204 or with other media. Semi-rigid or rigid film 204 is preferably of a higher hardness, density, ductility, and/or tensile property than the cross-linked foam 103. In one example, the semi-rigid or rigid film 204 has less flexibility than the closed cell foam 103. When support 100 is coupled with semi-rigid or rigid film 204, as in support to 200, 300, the flexible foam 103 acquires the semi-rigid or rigid functionality while maintaining an inner “core” sustaining the functionality of the foam 103. This structure has the advantage of light weight, floatability, insulation or conductivity, FR performance etc., with increased mechanical hardness and configurability or adaptability to carry the photovoltaic panel 400 or other flexible PV panel, e.g., to function as roofing for a car park, shelter or other purpose besides floating on liquid. Thus, while the semi-rigid or rigid film 204 is harder that support 100 (given its thickness and density) the photovoltaic panel 400 has some flexibility. Such foam with semi-rigid or rigid film 204 is commercially available from Palziv, Inc. (Ein Hanatziv, Israel).

The semi-rigid or rigid film 204 has a thickness of about in 0.2 mm to about 3.0 mm. The semi-rigid or rigid film 204 can be applied to the foam 103 by way of lamination or other binding/bonding methods and processes known in the art. In one example, the semi-rigid or rigid film 204 is flame-laminated to support 100. In another example, the semi-rigid or rigid film 204 is extrusion laminated to support 100. In another example, a sheet of semi-rigid or rigid film 204 is calendared with support 100 and heat bonded, ultrasonically bonded or adhesively bonded. In one example, support 100 can be manufactured in accordance with co-assigned U.S. Patent Application Publication 2018/0345642, which is incorporated herein by reference. In one example, the semi-rigid or rigid film 204 is high density polyethylene (HDPE) or ultrahigh molecular weight polyethylene (UHWPE).

As shown in FIG. 2C, support 300 is sandwiched between layers of the semi-rigid or rigid film 204 on opposing surfaces. In one example, semi-rigid or rigid film 204 can be the same on both sides of support 300. In another example, semi-rigid or rigid film 204 can be composed of laminate or bonded films from different polymers and/or copolymers, polymer molecular weights, thickness and physical properties. The side edges of support 300 can be uncoated or coated with the semi-rigid or rigid surface film or with other media. With reference to FIG. 2C, support 200 is depicted as a closed cell foam 103 having opposed semi-rigid or rigid films 204 along the length and width direction of the generally rectangular shape as described for support 100. The side edges of support 300 can be uncoated or coated with the semi-rigid or rigid film or with other media. Supports 100, 200, or 300 can be of monolithic configuration.

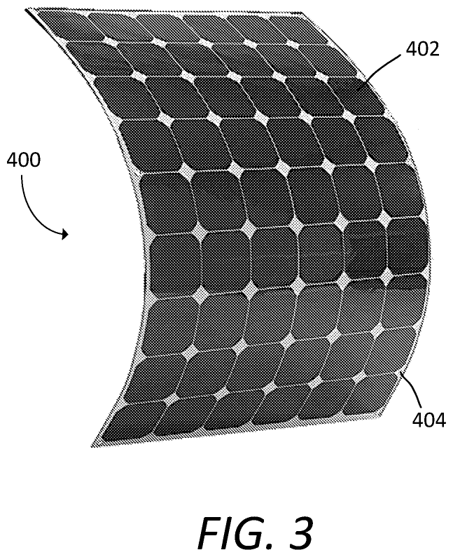

FIG. 3 depicts an example of a flexible photovoltaic panel 400 comprising one flexible substrate 404 on which are directly coupled one or more photovoltaic elements 402 and associated electrical controller and/or connections and/or cables. Flexible substrate 404 can be woven or nonwoven fabric impregnated with acrylic, polyester, polyamide, polypropylene, or a composite material reinforced with fibers of glass, carbon, or nylon, or another polymer foil structure.

In one example, photovoltaic panel 400 in one example is made of crystalline silicon solar cells, laminated to a glass-fiber reinforced composite carrier. The photovoltaic panel 400 has a thin profile and is semi-rigid due to flexible substrate 404 and thus can withstand some bending without breaking. In another example, photovoltaic panel 400 is glass-free and is flexible and can withstand bending without breaking. In one example, photovoltaic panel 400 has a bulk density of about 2.5 kg/m² to about 5.0 kg/m², depending on the configuration of the one or more photovoltaic elements 402. Photovoltaic panel 400 dimensions (length and width) can be customized to the dimensions of support 100, 200, or 300 or vice versa. In one example, photovoltaic panel 400 is glare-free so as not to disturb its surrounding with reflected light.

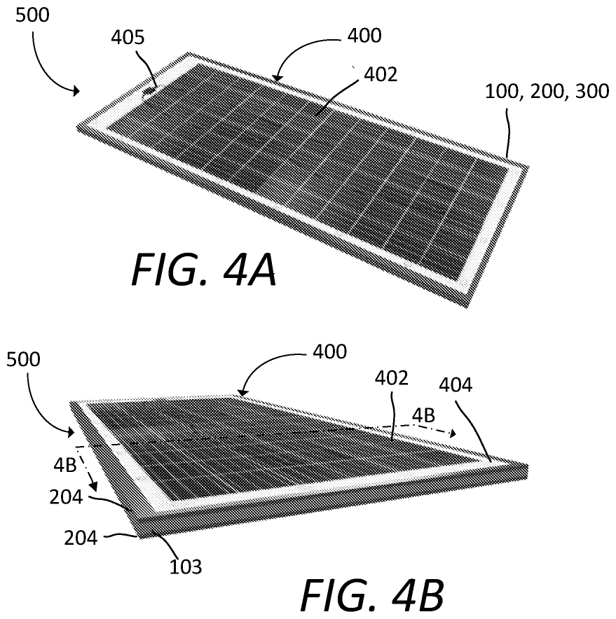

FIGS. 4A and 4B depict various perspective views of exemplary photovoltaic support systems 500, where system 500 comprises foam support 100, 200, or 300, the foam support having coupled or directly coupled thereto one or more flexible substrates 404, where each flexible substrate 404 comprises one or more photovoltaic panels 400 coupled or directly coupled thereto, each panel 400 comprising one or more photovoltaic elements 402 for solar conversion as well as electrical cable 405. Flexible substrate 404 can be reversibly or irreversibly coupled or directly coupled to foam support 100, 200, or 300 by gluing, welding/laminating or mechanical fixtures (e.g., with bolts or other fastening means). Flexible substrate 404 can be reversibly coupled to foam support 100, 200, or 300 for ease of replacement/repair. In one example, the foam support has semi-rigid or rigid film 204 directly coupled thereto and the one or more flexible substrates 404 are reversibly or irreversibly coupled or directly coupled to the semi-rigid or rigid film 204.

In one example, the exemplary photovoltaic panel support system 500 can be provided as a 2.4 meter×1 meter (L×W) product with a weight of about 10 kg to about 15 kg such that it can be carried by a single person. In one example, in the absence of semi-rigid or rigid film 204, the presently disclosed photovoltaic panel support system 500 can be configured to be rolled or folded for transport and/or deployment. The exemplary photovoltaic devices can be configured to be interlocking structures of the same or different dimensions/shape so as to be arranged in an array or other structural shape or form, and easily stacked and/or transported.

Given closed-cell support 100, 200, or 300 construction is of bulk density much less than that of water, and the combined bulk density of the support and flexible substrate is less than the density of water (fresh and saltwater), the presently disclosed photovoltaic panel support system 500 floats on water, e.g., with about 50-70% of the horizontal thickness of the support remaining above water.

For aesthetics purposes (e.g., landscaping or artistic expression), the presently disclosed photovoltaic panel support system 500 and/or the photovoltaic panel 400 can be provided in various colors.

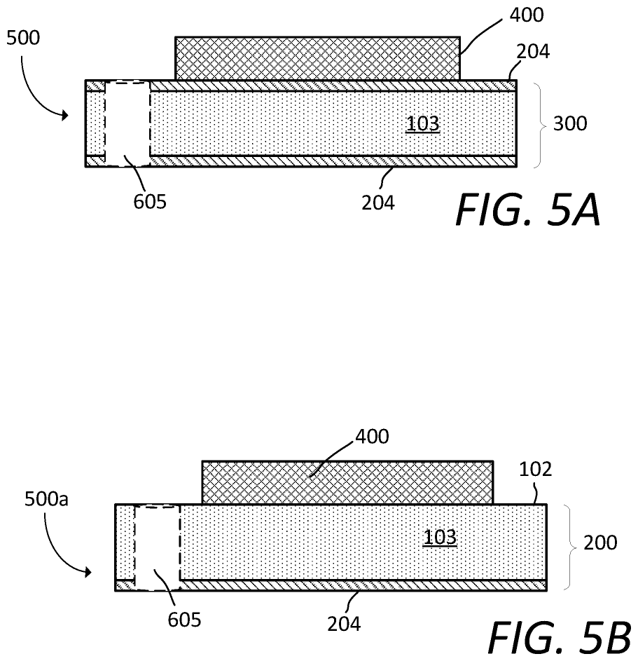

FIG. 5A depicts a sectional view along sectional line 4 of the flexible photovoltaic support of FIG. 4B of photovoltaic panel support system 500 having closed cell foam support 300 with photovoltaic panel 400 positioned on semi-rigid or rigid film 204 laminated to foam 103. Optional cutouts 605 that extend partially or completely through the thickness of support 300 can be employed, for example, for mounting of photovoltaic panel 400 or for housing and insulation of various components, such as a control box or cabling, or for reducing the overall weight of photovoltaic member.

FIG. 5B depicts a sectional view of an alternative photovoltaic panel support system 500a having closed cell foam 103 with photovoltaic panel 400 positioned directly on surface 102 of support 200 which has semi-rigid or rigid film 204 coupled to opposite surface 102.

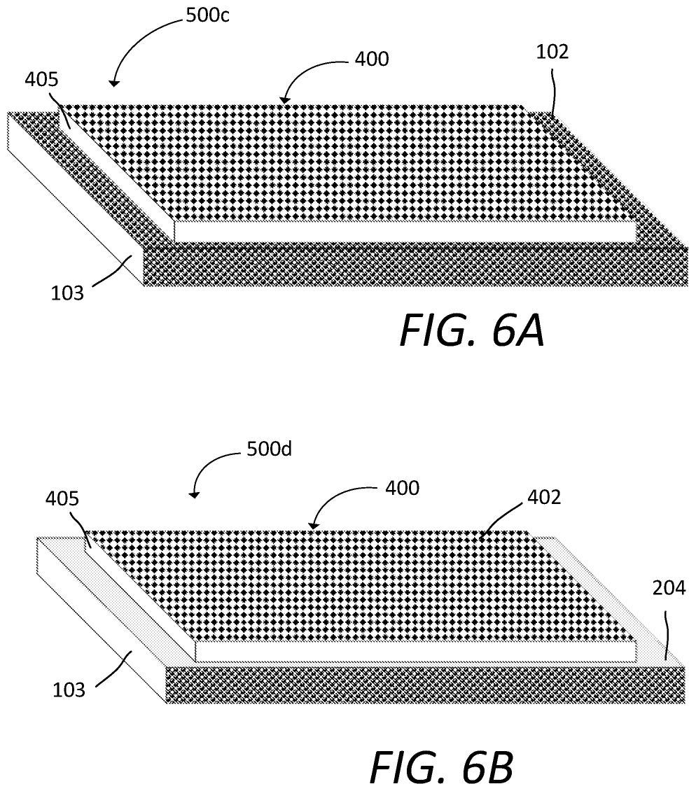

FIG. 6A, depicts exemplary photovoltaic panel support system 500c having photovoltaic panel 400 directly coupled to surface 102 of support 100 (or support 200). FIG. 6B depicts exemplary photovoltaic panel support system 500d having photovoltaic panel 400 directly coupled to semi-rigid or rigid film 204 of support 300.

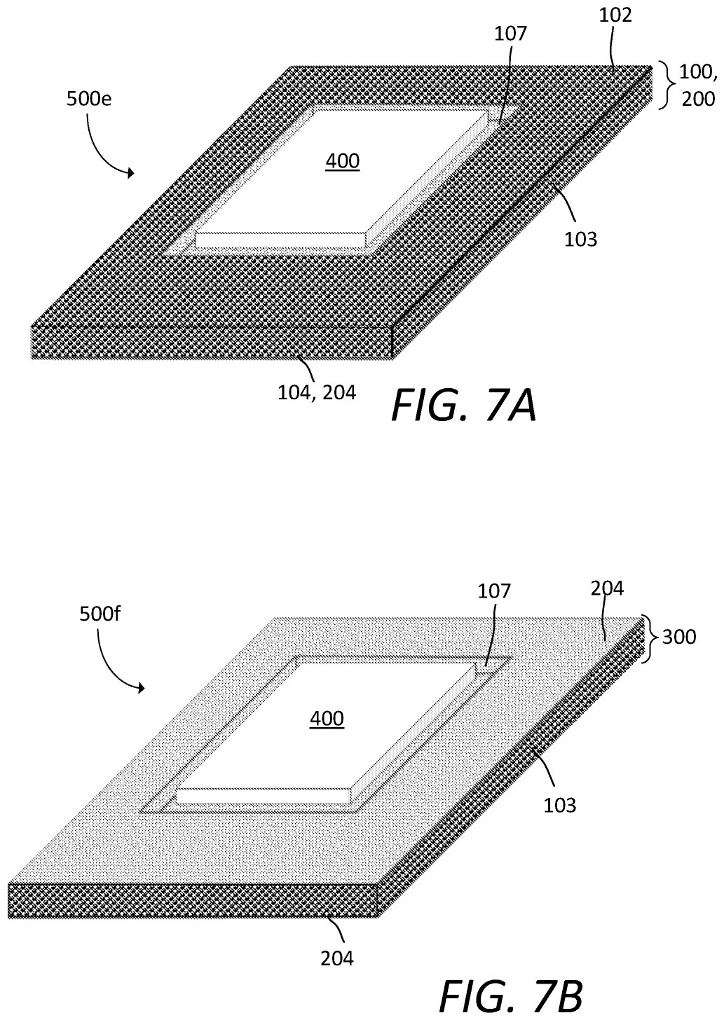

FIG. 7A depicts another exemplary photovoltaic panel support system 500e having recess 107 in surface 102 of either support 100, 200, recess 107 sized to receive one or more photovoltaic panels 400, among other things. FIG. 7B depicts another exemplary photovoltaic panel support system 500f having recess 107 in semi-rigid or rigid film 204 of support 300, where recess 107 is sized to receive one or more photovoltaic panels 400 among other things. In one example, one or more of the sidewalls and bottom surface of the recess 107 are configured with semi-rigid or rigid film 204. In one example, all of the sidewalls and bottom surface of the recess 107 are configured with semi-rigid or rigid film 204. In another example, one or more of the sidewalls and bottom surface of the recess 107 exposes foam 103 without semi-rigid or rigid film 204.

Photovoltaic panel support system 500 can be configured such that photovoltaic panels 400 are angled from horizontal (e.g., the horizon) to improve or maximize exposure to ambient light such as sunlight. For example, support 100, 200, 300 can be configured with a linearly variable thickness across the width of the support, e.g., a wedge-type shape or an additional piece of foam or other fixture that shall generate an angle. Alternatively, photovoltaic panels 400 can be mounted on support 100, 200, 300 angled from the horizontal surface of the support.

In one example, a plurality of photovoltaic panel support system 500 are connected in electrical communication with one another via connectors and fixtures as is known in the art. In one example, two or more photovoltaic panel support systems 500 can be configured as an array for deployment on land or on a liquid surface or body of water (saltwater or freshwater).

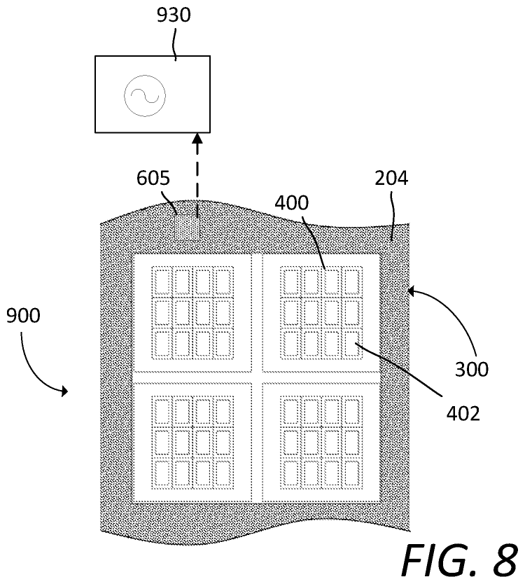

FIG. 8 depicts a top plan view of exemplary photovoltaic support system 500 each having photovoltaic panels 400 with a plurality of photovoltaic elements 402 arranged on semi-rigid or rigid film 204 of support 300 with optional cutouts 605 that extend partially through the thickness of support 300 for containing electrical components, among other things. Cutouts 605 can be configured, for example, to provide an interference fit of such electrical components within the support 100, 200, 300. Photovoltaic panel 400 typically includes a controller, as well as electrical cables 405 that can be embedded in cutouts such as 605 inside the support 100, 200, 300, for example using CNC milling, laser or water jet cutting, etc. As the electronics are sensitive parts of the photovoltaic panel 400, encapsulation within the support 100, 200, 300 provides environmental protection from the elements and thus longer shelf-life.

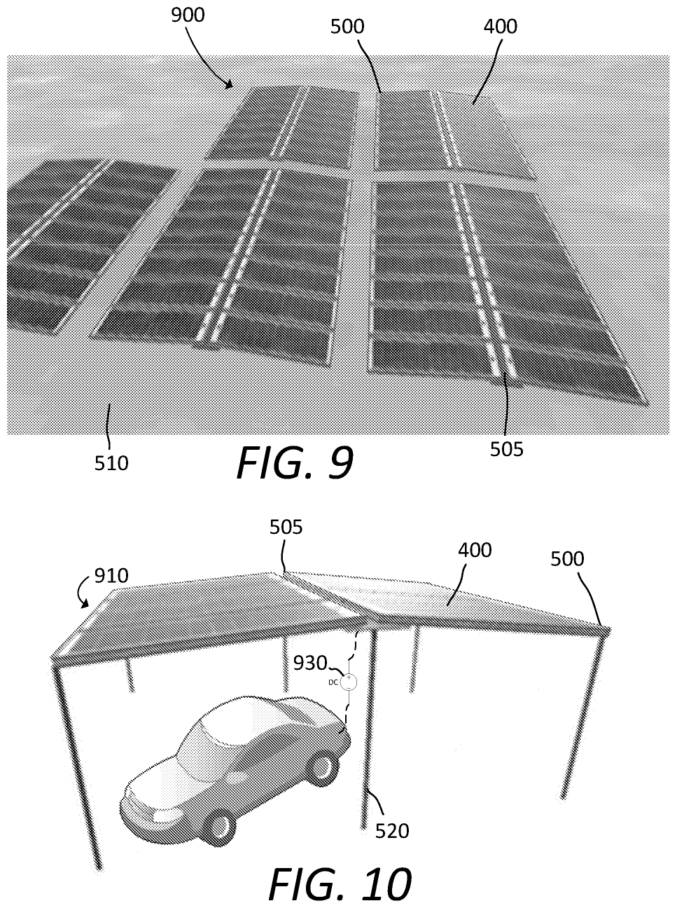

Likewise, FIG. 9 depicts photovoltaic support system array 900 comprising a plurality of photovoltaic panels 400, each with one or more photovoltaic elements 402, whereas system array 900 is positioned and/or suspended on a liquid surface 510. System array 900 is configured with channel 505 for example, for providing electrical coupling of the individual panels 400 or individual photovoltaic panel support system 500 among other things, such as a walkway for facilitating maintenance and/or repair. One or more arrays 900 can independently be configured electrically in series or in parallel with other systems so as to provide a solar energy farm, e.g., floating or land-based, that is constructed in a modular manner for assembly/disassembly as best suits the particular location. Electrical wiring can be provided from one photovoltaic panel support system 500 to another and as output from the system array 900. In one example, one or more photovoltaic panel support system 500 or system array 900 are electrically coupled to a variety of devices, such as for example, a DC/AC inverter/converter 930 so as to provide the appropriate current for use and/or storage by a user or for presenting to the grid.

Photovoltaic panels 400 of system array 900 can be arranged at a slight angle from horizontal, for example, using a wedge shaped channel 505. In one example, one or more of the plurality of individual panels 400, support systems, or the entire system array 900 can be arranged at an inclination of about 2° (degrees) to about 90° (degrees), or at an inclination of about 2° (degrees) to about 50°, or at an inclination of about 2° (degrees) to about 25°, or at an inclination of about 2° (degrees) to about 5°, relative to the horizon, in order to facilitate the removal of dust, for example, by rain or dewdrops. Alternatively, photovoltaic support system 500 can be configured horizontally or vertically (such as a façade for a building). In such case, cleaning can take place in another manner, e.g., when on liquid by accessing panels 400 of system array 900 by boat and utilizing high-pressure water.

In one example, photovoltaic panel 400 and support, or a plurality of photovoltaic supports configured as a system array 900, for example, is employed on a liquid surface or body of water to reduce or eliminate evaporation of the liquid substance or water by blocking the sunlight and corresponding heat and, in case of vapors, allowing the liquid substance to condense on the underside surface of one or more of the plurality of photovoltaic panels 400 or the system array 900. Liquid substances include, for example, fuels such as gasoline, diesel, and kerosene as well as hydrocarbons, solvents, and water.

System array 900 is configurable with no moving parts, hence requiring very little maintenance. Access to system array 900 after deployment on a body of liquid can be provided by boat, the above-mentioned channel 505 or, by towing the units to land (or the edge of the pool as this is easily done given the light weight of the photovoltaic panel 400). Likewise, the lightweight functionality of the system array 900 also facilitates disassembly and transportation. In one example, the presently disclosed photovoltaic support system array 900 is configurable as interconnecting panels that can be stacked for efficient transportation and deployment, for example, configurable as panels having length×width dimensions of 2.4 meter×1 meter (about 7.8 feet×3.3 feet), 1.8 m×1.2 m (6 ft×4 ft), 3 m×1.8 m (10 ft×6 ft), etc.

Likewise, FIG. 10 depicts photovoltaic support system 910 comprising one or more photovoltaic panel support system 500 suspended vertically or at an angle from a horizon from a solid surface via supports 520, for example, to provide shelter, carport, or storage area. In one example, the presently disclosed devices and systems can be used as a stand-alone shelter, mounted on simple beams or other known frames. The presently disclosed devices and system can be configured for temporary use or permanent use. In one example, the presently disclosed devices and system can be configured for use in carports or parking lots to facilitate charging of electrical vehicles.

In one example, rather than being of one integral part with optional recesses and/or cutouts as described above, the presently disclosed support 100, 200, 300 can be configured for assembly via of a number of independent, pre-cut parts. The independent pre-cut parts allow the structure to be lighter in weight and sized to fit various photovoltaic panels 400. The cumulated mass of the independent, pre-cut parts are configured so as to assure floatation when assembled while carrying the weight of one or more photovoltaic panels 400.

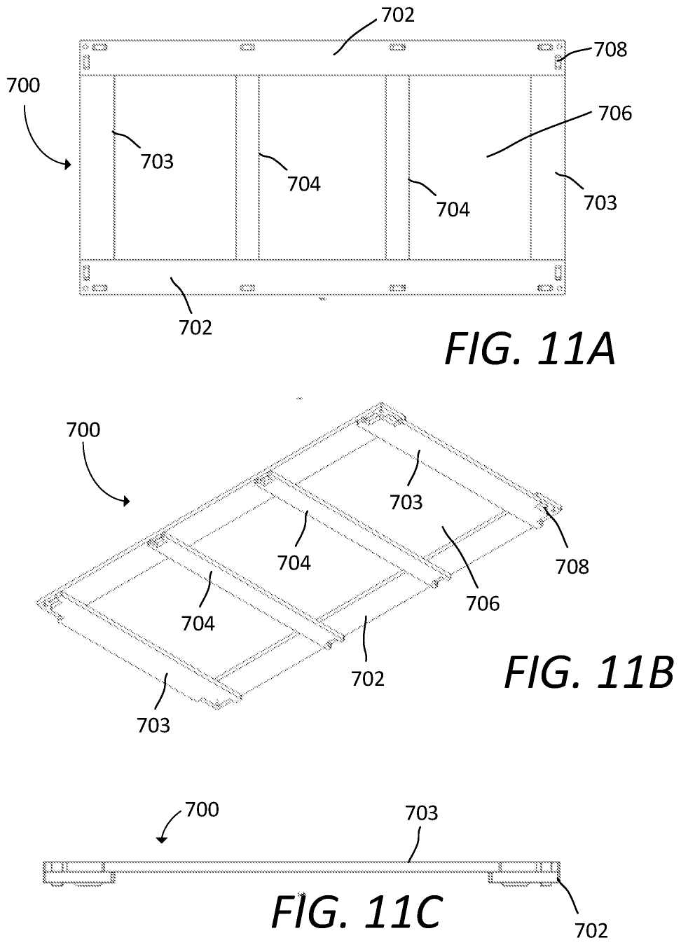

Thus, FIGS. 11A, 11B, and 11C depict a top plan view, bottom perspective view and side plan view of an exemplary thin-profile photovoltaic support 700 having a generally rectangular shaped frame with generally rectangular openings 706 assembled from independent longitudinal members 702, end cross-members 703, and mid-cross-members 704 (or cross-members) configured with joining members 708. In one example, longitudinal members 702, end cross-members 703, and mid-cross-members 704 are constructed of foam support 100, 200, or 300 as disclosed and described herein. In one example, joining members 708 are fasteners such as bolts and nuts, or adhesive. In another example, the joining members 708 are interlocking configurations integral with the members 702, 703 and 704. In another example, independent longitudinal members 702, end cross-members 703, and mid-cross-members 704 are configured for assembly to form the floating support structure using interlocking fixtures present on the corresponding members, which may click into place without bolts, screws, adhesive, lamination etc.

In one example, one or more photovoltaic panels 400 are laminated or physically secured to the support 700 using various securement methods, as previously described herein. In one example, one or more photovoltaic panels 400 are secured in place via a resistance fitting, using pressure obtained by the assembly of the independent longitudinal members 702, end cross-members 703, and mid-cross-members when assembled about the perimeter of the photovoltaic panel 400. One or more of the independent longitudinal members 702, end cross-members 703, and mid-cross-members can be configured with a plurality of joining members 708 for providing adjustment of the pressure provided to the perimeter of the photovoltaic panel 400.

In on example, the surface of support 700 may be vertically raised from the water in order to provide a minimum distance of the photovoltaic panel 400 from the surface of the water, as per local regulation. Thus, the support 700 can further comprise of additional foam elements as “carriers”, on the surfaces in contact with the water. In one example, the carriers are compatible with the joining members 708 for attachment to support 700. In one example, support 700 is configured to hold the weight of one or more photovoltaic members 400 and remain afloat on fresh or salt water.

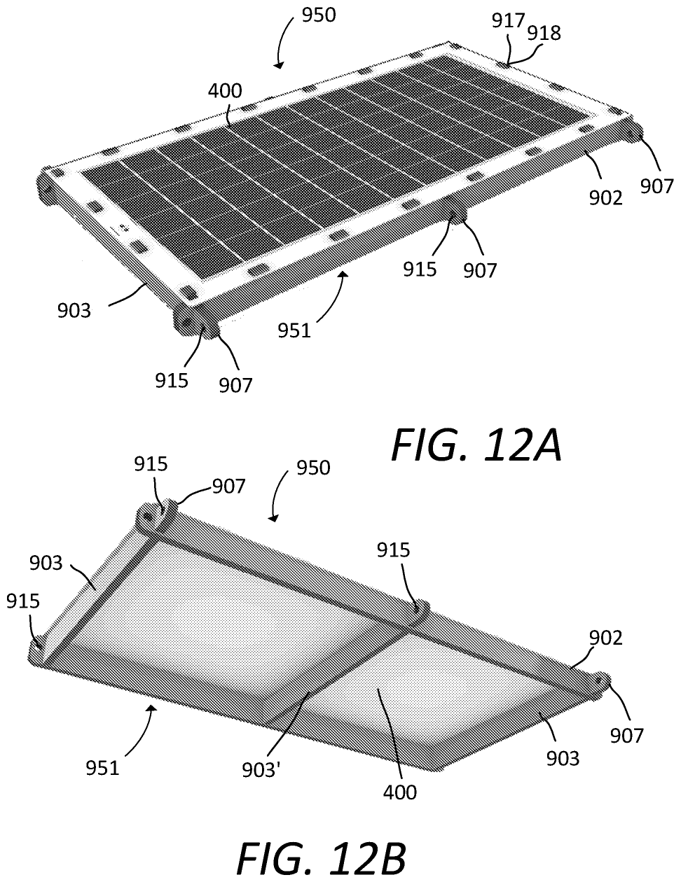

FIG. 12A depicts a top perspective view of another exemplary photovoltaic support system 950 providing a generally horizontal platform support 951 for receiving photovoltaic panel 400. Thus, exemplarily support 951 is shown in FIG. 12A, having a four (4) bar system, comprising at least 2 longitudinal members 902 and at least two cross-members 903 that provide for a generally rectangular frame, and optionally include one or more additional cross-members 903′ to the frame for reinforcement purposes. In one example, support 951 provides for all of the longitudinal and cross-members 902, 903, 903′ to lock into each using an interlocking fixture method, for example, as disclosed in co-assigned U.S. Pat. No. 9,724,618, incorporated herein by reference, and further discussed below. In one example, the longitudinal and cross-members 902, 903, 903′ are pre-cut with integrated, interlocking protruding receiving members 917 to receive and secure a PV panel into place. In one example, support 951 is configured to receive a PV panel that is pre-drilled with one or more openings 918 sized and arranged for receiving protruding receiving members 917 of the longitudinal members and cross-members 902, 903, 903′.

In one example, the PV panel is “clicked” into support 951 by applying some pressure. In another example, one side of the longitudinal member 902 will be slightly higher than the adjacent side, in order to angle the surface of the PV panel, e.g., for rain and dewdrops to clean the surface. In one example, the height/thickness of support 951 is configured to be about 50 mm to about 200 mm for providing a thin profile, but this dimension may vary, depending on local regulation as to a required distance of the PV panel from the surface of the water, for example. In another example, the length and width of support 951 is configured to be about 2000 mm×1000 mm, but this may also vary based on the dimensions of the PV panel among other things.

A plurality of eyelets 915 protruding from support 951 allow connection between any number of supports, or systems (each carrying its PV panel). When longitudinal members 902 and cross-members 903 are assembled to form the support 951, members 907 project from the lateral and transverse edges so as to provide means to join a plurality of supports 951 or systems 950 together along one or both edges. For example, one or both of longitudinal members 902 that receive PV panel can be configured with a width so as to be received by a single cross-member 903. Support 951 provides for optimized storage and transportation of system 950. Support 951 includes eyelets 915 at both the termini of longitudinal members 902 and cross-members 903 for connecting two or more supports together along their respective longitudinal and/or transverse edges, e.g., for providing a one-dimensional or two-dimensional array, for example using rope or cable.

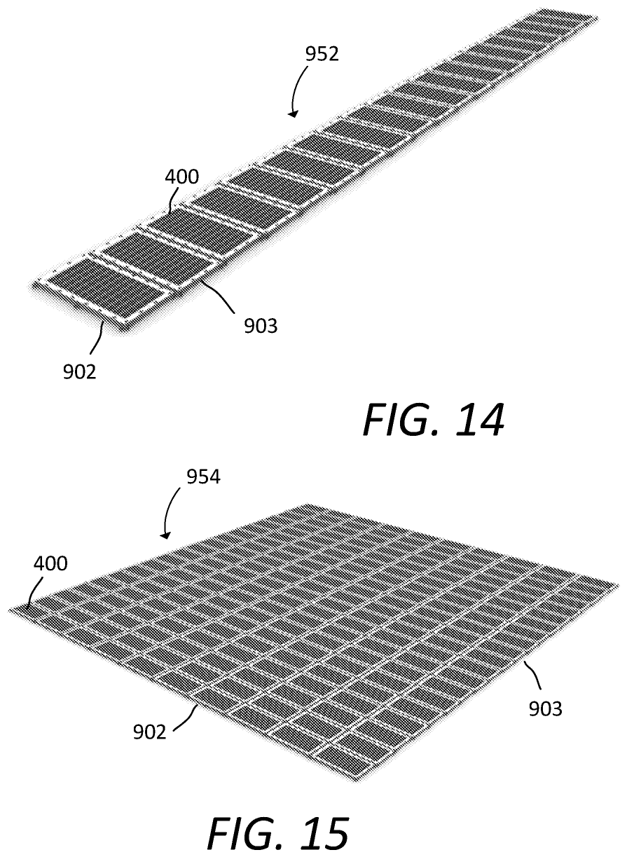

FIG. 12B depicts a bottom perspective view of the photovoltaic support 951 and system 950 of FIG. 12A showing longitudinal members 902 and cross-members 903 with receiving members 917 for receiving corresponding PV panel cutouts 905. FIGS. 14A and 14B represent one of a variety of possible architectures where flexible photovoltaic panel 400 or conventional non-flexible PV panels are fixated in a format which the PV panel is positioned substantially horizontal to the plane of the support system 950, and/or as well as horizontal to a surface of a body of water, or landscape, etc. FIGS. 12A and 12B depict the PV panel 905 coupled to the support 951 with a substantially horizontal arrangement, however, alternate arrangement, e.g., tilting, of the surface of the PV panel are envisioned. The technical advantages of system 950 include efficient production and the utilization of floating foam support; a strong and robust architecture suitable for both lightweight flexible PV panels as well as conventional glass PV panels; transportable as flat/stackable kits; easily assembled (and disassembled) at the location of deployment; and provide for customization to different cases (e.g., regulation, availability of PV elements, etc).

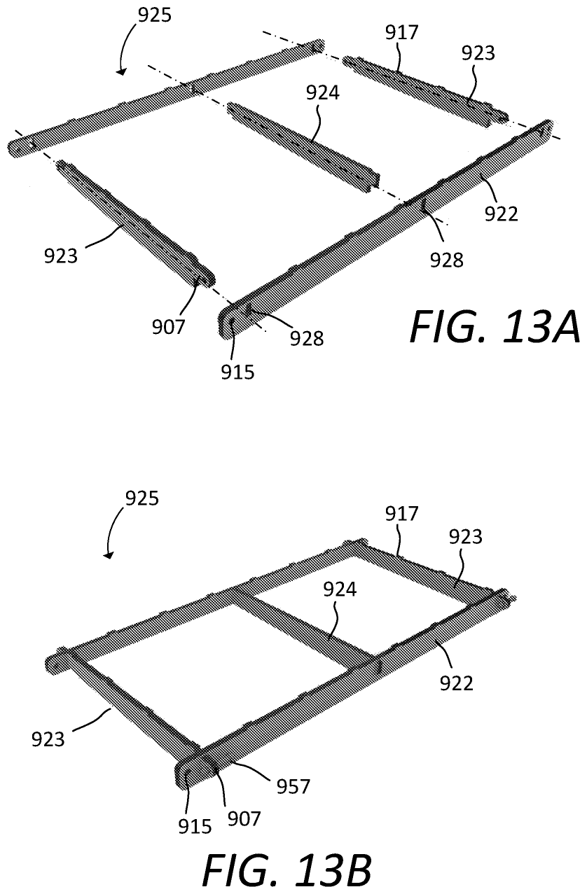

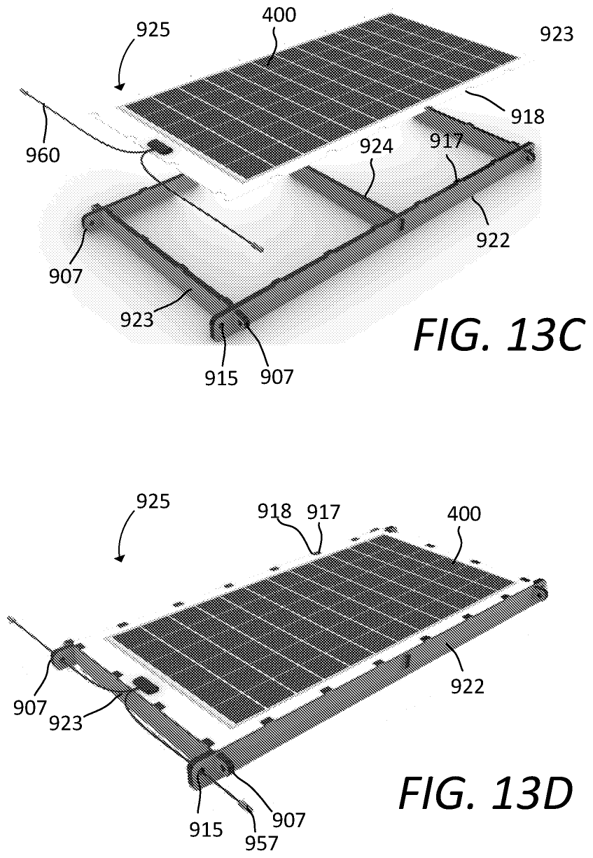

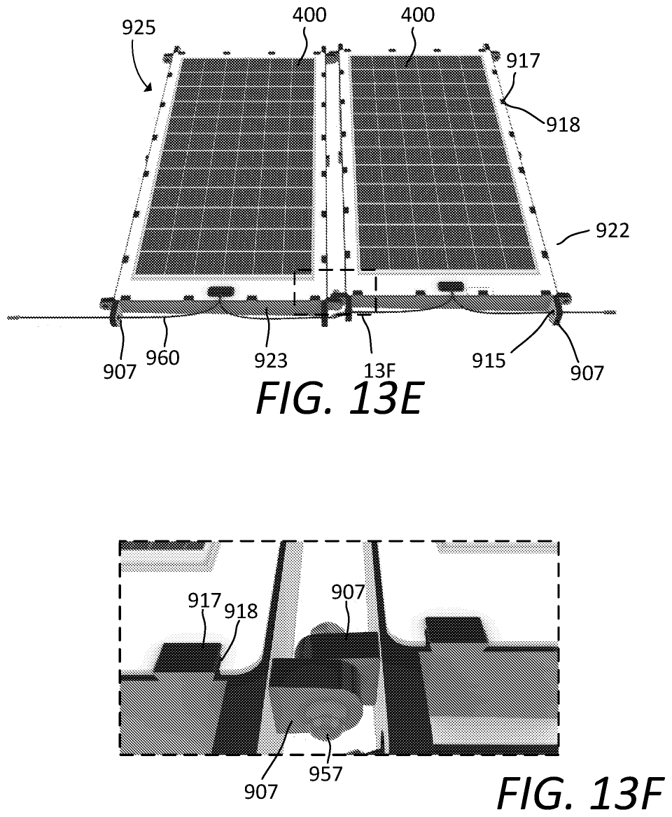

FIGS. 13A and 13B depict an exploded un-assembled view and assembled view, respectively, of an exemplary photovoltaic support system 925, where longitudinal members 922 can be coupled with cross-members 923 and optional mid-section cross-member 924 so as to receive and support a PV panel discussed in more detail below. In one example, member 907 of cross-member 923 is configured for coupling with opening 927 of longitudinal member 922, for example, snap-fit. In one example, longitudinal members 922 and cross-members 923, 924 are constructed of closed cell foam support 100, 200, or 300 as previously described. The length, width, height, density, and color of the longitudinal members 922 and cross-members 923, 924 can be configured to accommodate PV panels of varying dimensions or other circumstances.

FIGS. 13C and 13D depict an un-assembled view and assembled view, respectively, of the exemplary photovoltaic support system 925 of FIG. 13B with photovoltaic panel 400. Longitudinal members 922 and cross-members 923 include protruding receiving members 917 that are configured to be received by openings 918 of photovoltaic panel 400 to secure the photovoltaic member to the support system. In one example, receiving members 917 are dimensioned so as to snap-fit with openings 918 of photovoltaic panel 400. In one example, receiving members 917 are protruding interlocking fixtures that are partially or completely encircled/enclosed by the openings 918 of the photovoltaic panel 400. In the assembled state, openings 918 can be configured to receive a lid or cover to seal or otherwise restrict access of environmental elements between the photovoltaic panel 400 and support system 925. Eyelets 915 of longitudinal member 922 can receive electrical conduits/cables 960 from photovoltaic panel 400.

FIG. 13E depicts a plurality of physically coupled photovoltaic supports 925 of FIG. 13D with electrically coupled photovoltaic panels 400, connected via members 907 of adjacent longitudinal members 922 with coupling means 957. FIG. 13F is an enlarged view of exemplary coupling means 957 positioned between adjacent cross-members 923 of separate support systems 925. Exemplary coupling means 957 includes nuts and bolts (plastic or metal), cotter pins, bungee cords, and the like. Coupling means 957 can be of two-part construction that reversibly locks together when joined after insertion of members 907 of cross-members 923 into openings 928 of longitudinal members 922.

FIG. 14 depicts a linear array 952 construction of the photovoltaic support system of the present disclosure, defined by length 903 and width 902, and supporting a plurality of photovoltaic panels 400 coupled together at their respective longitudinal edges 902 by way of fixtures or cutouts and/or snap-fit features.

Likewise, FIG. 15 depicts a two-dimensional array 954 defined by longitudinal and transverse edges 902, 903 and supporting a plurality of photovoltaic panels 400 coupled together at their respective longitudinal and transverse edges 902, 903, respectively.

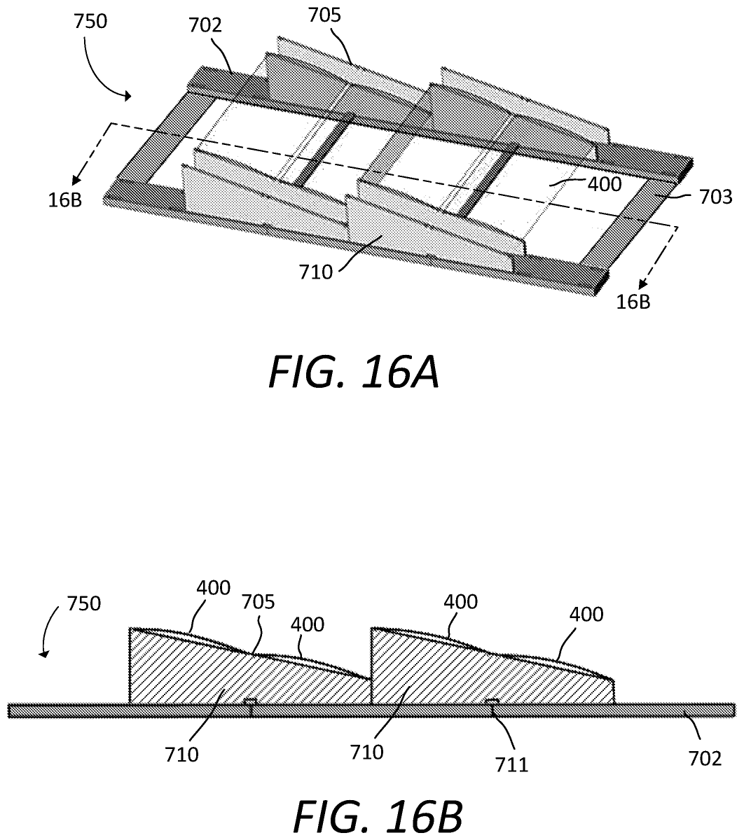

FIG. 16A depicts a top perspective view of an exemplary photovoltaic support system 750 having support 700 with vertically extending supports 710 projecting from longitudinal members 702. Vertically extending supports 710 can be secured to longitudinal members 702 by way of fixtures 711. A plurality of fixtures 711 can be configured on longitudinal members 702 for adjusting the positions of vertical extending supports 710 as needed to accommodate various sized photovoltaic panels 400. Distal edge 705 of vertically extending supports 710 can be raised and/or placed at an angle from horizon to improve or maximize exposure as shown. Pairs of vertically extending supports 710 with angled distal edges 705 are spaced apart across cross-members 703 a distance commensurate with the width of photovoltaic panel 400 or other flexible PV panel, so as to angle the solar cell surface thereof relative to the horizon, as disclosed and described herein. The choice of such angle is in part dictated by the specific area of the world where such system a system would be deployed so as to provide for optimized efficiency in exposure to ambient light such as sunlight, and the subsequent collection of solar energy by the system.

FIG. 16B depicts a section view along line 16B-16B of the photovoltaic support system of FIG. 16A showing distal edge 705 of vertically extending supports 710 with surface of photovoltaic panel 400 angled downwardly along longitudinal axis of support 700 as shown.

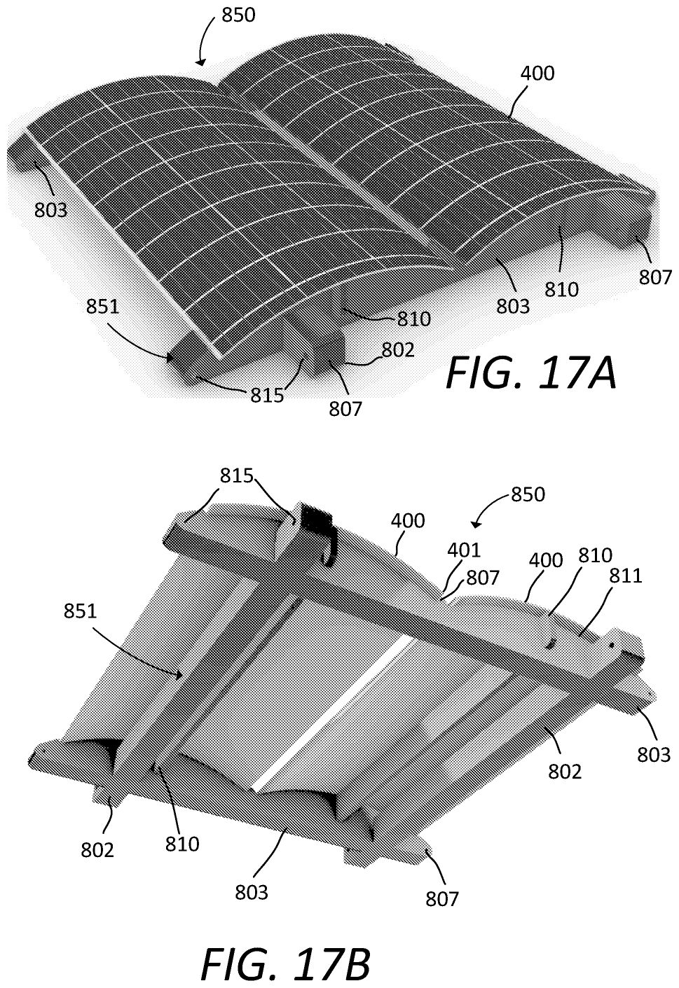

FIG. 17A depicts a top perspective view of another exemplary photovoltaic support system 850 providing a generally concave platform for receiving photovoltaic panel 400. System 850 comprises a plurality of cross-members 803 and a plurality of longitudinal members 802. At least two of the cross-members 800 have a concave or bowed receiving surface 811 to receive photovoltaic panel 400 and present panel 400 in a concave or bowed configuration. Cross-members 800 can be secured to longitudinal members 802 by way of fixtures or cutouts and/or in a snap-fit arrangement. Additional horizontally offset longitudinal members 810 can be provided to support the photovoltaic panel 400 along its longitudinal length, e.g., along its center longitudinal line, when arranged in a concave or bowed configuration. Cross-members 803 are shown configured with cut out 807 to receive and secure longitudinal edges 401 of photovoltaic panel 400. As shown, a pair of cross-members 803 arranged with a pair of longitudinal members 802 and additional longitudinal members 810 can be configured with a plurality of photovoltaic panels 400. The thickness of cross-member 803 can be varied along the longitudinal direction of the support. System 850 provides for optimized efficiency in exposure to ambient light such as sunlight, and the subsequent collection of solar energy by the system.

FIG. 17B depicts a bottom perspective view of the photovoltaic support system 850 of FIG. 17A showing support 851 having cross-members 803 with concave or bowed receiving surface 811 connected to longitudinal members 802. FIG. 17A represents one of a variety of possible architectures where the flexibility of photovoltaic panel 400 or other flexible PV panel allows for fixation to support 851 in a format in which the PV panel is not substantially flat, but rather concave or bowed. FIGS. 17A and 17B depict the flexible PV panel coupled to support 851 with a substantially symmetric concave or bow arrangement, however, alternate asymmetric curvature of the surface of the PV panel are envisioned. Support 851 includes eyelets 815 at the termini of longitudinal members 802 and cross-member 803 for connecting two or more supports together or for securing.

At least one technical benefit of the support system 850 would be to obviate the need to target any specific angle for the support and/or PV panel for receiving sunlight. Support system 850 would provide easier maintenance due to the curvature imparted on the photovoltaic panel 400 or other flexible PV panel that would facilitate self-cleaning by rain or dew.

In one example, a combination of system 850 with one or more systems 750 or array 900 is provided. In another example, system 850 is used alone or with one or more systems 750 and/or array 900 for providing different shapes of a plurality of PV's for presenting an architectural sculpture-like arrangement, either on water or in a field. One or more parts of support system 850 with one or more supports 100, 200, or 300 can be provided as a systems with one or more colors, patterns and/or text for aesthetics and/or advertising. In one example, the system is configured such that the PV panels change in form, or orientation of one or more supports or panels over a period of time, creating a dynamic visual appearance. Such control of the form or orientation of one or more supports or panels of the system can be, for example, remotely or digitally controlled and/or scheduled for specific times during a time period.

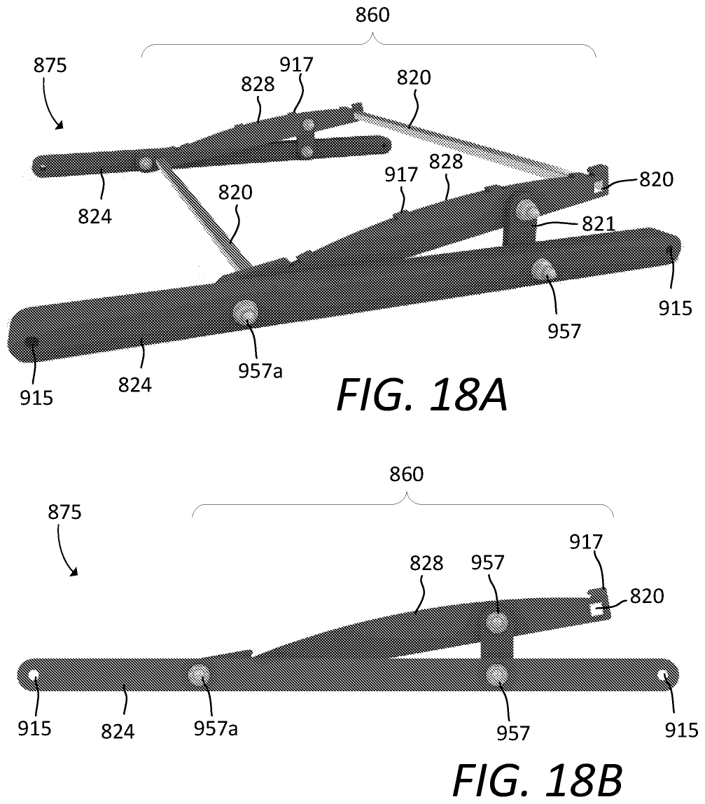

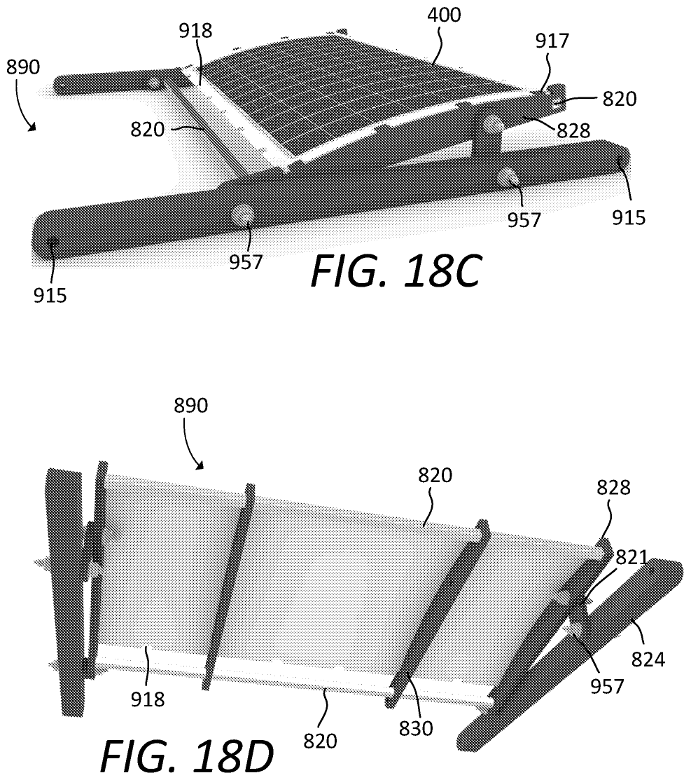

FIGS. 18A and 18B, 18C and 18D depict a perspective view and a side view, respectively, of an exemplary adjustable photovoltaic support 875 having an outer frame having longitudinal members 824 with an inner frame 860. Members 828 of inner frame 860 are coupled together by cross-members 820. Inner frame 860 is pivotably coupled to outer frame, for example, as shown, at connection 957a so as to provide for angled elevation of the inner frame relative to the outer frame. Arm 821 supports the section of the inner frame in the elevated position from the outer frame. In one example, arm 821 can be adjustably positioned along the longitudinal length of member 828 for providing different angled elevations of the inner frame 860. Member 828 has a photovoltaic panel facing surface that includes receiving members 917 for receiving openings 918 of photovoltaic panel. In one example, member 828 has a concave surface for receiving a photovoltaic panel. Support 875 has eyelets 915 at distal and proximal ends of the longitudinal members 824 for coupling to or more supports together as previously described.

FIGS. 18C and 18D depict a perspective view and a bottom perspective view, respectively, of the exemplary photovoltaic support system 890 comprising support 875 of FIG. 18A with photovoltaic panel 400 coupled to support 875 via receiving members 917 and openings 918 as previously described. Additional support members 830 coupled between cross-members 820 are shown, for example to support the weight of a conventional photovoltaic panel. Other configurations are envisioned.

1-25. (canceled)

26. A photovoltaic panel support system comprising:
a cross-linked closed cell foam structure having a first surface defined by a length and a width, and an opposing second surface separated from the first surface by a thickness; and
a rigid photovoltaic panel or a flexible photovoltaic panel coupled to the first surface of the cross-linked closed cell foam structure, the rigid or the flexible photovoltaic panel comprising one or more photovoltaic elements.

27. A photovoltaic panel support system of claim 26, wherein the cross-linked closed cell foam structure further comprises a semi-rigid or rigid film directly coupled on one or both of the first surface and the opposing second surface.

28. A photovoltaic panel support system of claim 27, wherein the rigid or the flexible photovoltaic panel is directly coupled to the semi-rigid or rigid film.

29. A photovoltaic panel support system claim 26, wherein at least a portion of the cross-linked closed cell foam structure is concave.

30. A photovoltaic panel support system claim 26, wherein the rigid or the flexible photovoltaic panel comprises acrylic, polyester, polyamide, polypropylene, or a composite material reinforced with fibers of glass, carbon, or nylon.

31. A photovoltaic support system claim 26, wherein one or more of the cross-linked closed cell foam structure is arranged in an array, the array arranged horizontally or at an inclination relative to a horizon of about 2 degrees to about 80 degrees.

32. A photovoltaic support system claim 26, wherein the cross-linked closed cell foam structure is arranged as a thin-profile frame, the frame comprising:
at least two longitudinal members;
at least two cross-members configured for securing to the at least two longitudinal members;
wherein the frame is configured to receive and secure the rigid or the flexible photovoltaic panel.

33. A photovoltaic support system of claim 32, wherein the frame receives and secures the rigid or the flexible photovoltaic panel without adhesive or fastenings.

34. A photovoltaic support system of claim 32, wherein at least a portion of the frame is concave.

35. A photovoltaic support system comprising a cross-linked closed cell flexible foam structure having a first surface defined by a length and a width, and an opposing second surface separated from the first surface by a thickness configured to receive a rigid photovoltaic panel or a flexible photovoltaic panel comprising one or more photovoltaic elements.

36. A photovoltaic support system of claim 35, further comprising a semi-rigid or rigid film directly coupled to the first surface or to both the first surface and the second surface, wherein the semi-rigid or rigid film coupled to the first surface is configured to receive the rigid or the flexible photovoltaic panel.

37. A photovoltaic support system of claim 35, further comprising a recess in the first surface and/or the semi-rigid or rigid film, the recess sized to receive the rigid or the flexible photovoltaic panel.

38. A photovoltaic support system of claim 35, wherein the cross-linked closed cell flexible foam structure is a frame comprising at least two longitudinal members; at least two cross-members configured for securing to the at least two longitudinal members; wherein the frame receives and secures the rigid or the flexible photovoltaic panel without adhesive or fastenings.

39. A photovoltaic support system of claim 35, wherein the cross-linked closed cell flexible foam structure comprises:
an outer frame comprising at least two longitudinal members and at least two cross-members; and
an inner frame positioned within the outer frame, the inner frame pivotably coupled to the outer frame, wherein the inner frame is configured for receiving and securing the rigid or the flexible photovoltaic panel without adhesive or fastenings such that the rigid or the flexible photovoltaic panel adjustably inclinable between about 2 degrees to about 80 degrees relative to a horizon.

40. A photovoltaic support system of claim 38, wherein at least a portion of the frame or the inner frame receiving and securing the rigid or the flexible photovoltaic panel is concave.

41. A method of reducing or eliminating evaporation of liquid, the method comprising
positioning, on at least a portion of a surface of a liquid body, a cross-linked closed cell foam structure having a first surface defined by a length and a width, and an opposing second surface separated from the first surface by a thickness, and a photovoltaic panel comprising one or more photovoltaic elements mounted thereon, the photovoltaic panel coupled to the first surface of a cross-linked closed cell foam structure; and
reducing or eliminating evaporation of liquid from the surface of the liquid body.

42. A method of claim 41, wherein the cross-linked closed cell foam structure further comprises a semi-rigid or rigid film directly coupled on one or both of the first surface and the opposing second surface.

43. A method of claim 41, wherein one or more of the cross-linked closed cell foam structures are arranged in an array, wherein the array is arranged linearly or two-dimensionally.

44. A method of claim 41, wherein the photovoltaic panel is adjustably inclinable to inclination of about 2 degrees to about 80 degrees relative to a horizon.

45. A method of claim 41, wherein at least a portion of the cross-linked closed cell foam structure is concave.
